(19) United States
(12) Patent Application Publication
(10) Pub. No.: US 2015/0244352 A1
(43) Pub. Date: Aug. 27, 2015

(54) POWER REDUCTION DEVICE AND METHOD

(71) Applicant: SAMSUNG ELECTRO-MECHANICS CO., LTD., Gyeonngi-Do (KR)

(72) Inventor: Kyoung Joong MIN, Gyeonggi-Do (KR)

(73) Assignee: SAMSUNG ELECTRO-MECHANICS CO., LTD., Gyeonggi-Do (KR)

(21) Appl. No.: 14/616,378

(22) Filed: Feb. 6, 2015

(30) Foreign Application Priority Data
Feb. 27, 2014 (KR) 10-2014-0023474

(51) Int. Cl. H03K 3/012; H03L 7/08; H03K 17/22

(52) U.S. Cl. CPC H03K 3/012; H03K 17/223; H03L 7/08

(57) ABSTRACT

Embodiments of the invention provide a power reduction device and method. According to at least one embodiment, there is provided a power reduction device, which includes an internal reset generating unit outputting an internal reset signal when a power supplying voltage is lowered from a normal state to a lower threshold voltage or less, and a power controlling unit outputting a power down signal after a predetermined time elapses when the internal reset signal is output from the internal reset generating unit. According to at least one embodiment, a power down mode in a chip is operated when a power lower than a reference is provided for a long time, thereby making it possible to reduce a current consumed in the chip.

### CROSS REFERENCE TO RELATED APPLICATION

This application claims the benefit of and priority under 35 U.S.C. §119 to Korean Patent Application No. KR 10-2014-0023474, entitled. “POWER REDUCTION DEVICE AND METHOD,” filed on Feb. 27, 2014, which is hereby incorporated by reference in its entirety into this application.

### BACKGROUND

1. Field of the Invention

The present invention relates to a power reduction device and method.

2. Description of the Related Art

In a general system on chip (SoC), a low voltage detecting device is a circuit generating a reset signal in the chip in the case in which a power supplied to the chip is unstable, thus, in the case in which the power is lower than a reference value set in the low voltage detecting device, thereby preventing a malfunction of the chip in an unstable power condition.

Recently, in accordance with the use of a mobile apparatus, the power may be instantaneously turned off depending on a power of a battery, and a power lower than a reference value may be supplied in the case in which the power of the battery is insufficient.

When the power supplied to the chip becomes unstable, a transistor circuit in the chip malfunctions to damage contents of a storage memory. A reset signal provided by the low voltage detecting device is maintained in the chip in order to prevent the serious malfunction as described above.

In this situation, in the case in which a voltage of the battery is insufficient, such that the power lower than the reference value is supplied for a long time, when a power down mode in the chip is operated using the reset signal generated by the low voltage detecting device to additionally provide a condition in which the chip may be operated at a low power, a current consumed in the chip may be reduced, for example, as described in Korean Patent Publication No. 2011-0036230.

### SUMMARY

Accordingly, embodiments of the invention have been made to provide a power reduction device and method capable of reducing a current consumed in a chip by operating a power down mode in the chip using a reset signal generated by a low voltage detecting device when a power lower than a reference is provided for a long time.

According to at least one embodiment of the invention, there is provided a power reduction device including an internal reset generating unit outputting an internal reset signal when a power supplying voltage is lowered from a normal state to a lower threshold voltage or less, and a power controlling unit outputting a power down signal after a predetermined time elapses when the internal reset signal is output from the internal reset generating unit.

According to at least one embodiment, the power reduction device further includes a power reset generating unit generating and outputting a power reset signal when the power supplying voltage is equal to or larger than a predetermined ratio of the normal state, a global reset generating unit outputting a global reset signal when the power reset signal output from the power reset generating unit and the internal reset signal output from the internal reset generating unit are in the same reset state, and a reset delay unit delaying and outputting the global reset signal output from the global reset generating unit.

According to at least one embodiment, the power reset generating unit includes a first voltage detector detecting a variation in the power supplying voltage, a power reset signal generator generating and outputting the power reset signal when the power supplying voltage detected by the first voltage detector is equal to or larger than the predetermined ratio of the normal state, and a power inverter inverting and outputting the power reset signal.

According to at least one embodiment, the global reset generating unit is a logical product circuit outputting the global reset signal when the power reset signal output from the power reset generating unit and the internal reset signal output from the internal reset generating unit are in the same reset state.

According to at least one embodiment, the power reduction device further includes a reset counter unit counting the number of clocks of a clock signal and outputting the counted number of clocks when the internal reset signal is output from the internal reset generating unit. According to at least one embodiment, the power controlling unit decides that the predetermined time has elapsed to output the power down signal, when the number of clocks input from the reset counter unit is a predetermined number or more.

According to at least one embodiment, the internal reset generating unit includes a second voltage detector detecting a variation in the power supplying voltage; an internal reset signal generator generating and outputting the internal reset signal when the power supplying voltage detected by the second voltage detector is lowered from the normal state to the lower threshold voltage or less, and an internal inverter inverting and outputting the internal reset signal.

According to at least one embodiment, the internal reset generating unit releases a reset state of the internal reset signal after a predetermined time elapses when the power supplying voltage is raised from the lower threshold voltage or less to an upper threshold voltage or more, and the power controlling unit releases a power down state of the power down signal when the reset state of the internal reset signal is released by the internal reset generating unit.

According to at least one embodiment, the power controlling unit outputs the power down signal to at least one of a phase locked loop (PLL) circuit, an oscillator, an analog to digital converter, and a digital to analog converter.

According to at least another embodiment of the invention, there is provided a power reduction method including (A) outputting, by an internal reset generating unit, an internal reset signal when a power supplying voltage is lowered from a normal state to a lower threshold voltage or less, and (B) outputting, by a power controlling unit, a power down signal after a predetermined time elapses when the internal reset signal is output from the internal reset generating unit.

According to at least one embodiment, the power reduction method further includes, before the step (A), (C) generating and outputting, by a power reset generating unit, a power reset signal when the power supplying voltage is equal to or larger than a predetermined ratio of the normal state, and after the step (A), (I)) outputting, by a global reset generating unit, a global reset signal when the power reset signal output from the power reset generating unit and the internal reset signal output from the internal reset generating unit are in the same reset state, and (E) delaying and outputting, by a reset delay unit, the global reset signal output from the global reset generating unit.

According to at least one embodiment, the step (C) includes (C-1) detecting, by the power reset generating unit, a variation in the power supplying voltage, (C-2) generating, by the power reset generating unit, the power reset signal when the detected power supplying voltage is equal to or larger than the predetermined ratio of the normal state, and (C-3) inverting and outputting, by the power reset generating unit, the power reset signal.

According to at least one embodiment, the power reduction method further includes, before the step (B), (F) counting the number of clocks of a clock signal and outputting the counted number of clocks, by a reset counter unit, when the internal reset signal is output from the internal reset generating unit. According to at least one embodiment, the power controlling unit decides that the predetermined time has elapsed to output the power down signal, when the number of clocks input from the reset counter unit is a predetermined number or more.

According to at least one embodiment, the step (A) includes (A-1) detecting, by the internal reset generating unit, a variation in the power supplying voltage, (A-2) generating, by the internal reset generating unit, the internal reset signal when the detected power supplying voltage is lowered from the normal state to the lower threshold voltage or less, and (A-3) inverting and outputting, by the internal reset generating unit, the internal reset signal.

According to at least one embodiment, the power reduction method further includes (G) releasing, by the internal reset generating unit, a reset state of the internal reset signal after a predetermined time elapses when the power supplying voltage is raised from the lower threshold voltage or less to an upper threshold voltage or more, and (H) releasing, by the power controlling unit, a power down state of the power down signal when the reset state of the internal reset signal is released by the internal reset generating unit.

According to at least one embodiment, in the step (B), the power controlling unit outputs the power down signal to at least one of a PLL circuit, an oscillator, an analog to digital converter, and a digital to analog converter.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a configuration diagram of a power reduction device according to at least one embodiment of the invention.

FIG. 2 is a waveform diagram for describing an operation of an internal reset generating unit of FIG. 1 according to at least one embodiment of the invention.

FIGS. 3 and 4 are waveform diagrams for describing a power down signal output from a power controlling unit of FIG. 1 according to at least one embodiment of the invention.

FIG. 5 is a detailed configuration diagram of a power reset generating unit of FIG. 1 according to at least one embodiment of the invention.

FIG. 6 is a detailed configuration diagram of an internal reset generating unit of FIG. 1 according to at least one embodiment of the invention.

FIG. 7 is a detailed configuration diagram of a global reset generating unit of FIG. 1 according to at least one embodiment of the invention.

FIGS. 8A and 8B are waveform diagrams for describing a global reset signal according to at least one embodiment of the invention.

FIG. 9 is a flow chart of a power reduction method according to at least one embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

FIG. 1 is a configuration diagram of a power reduction device according to at least one embodiment of the invention.

Referring to FIG. 1, a power reduction device according to at least one embodiment of the invention includes a power supplying unit 20, a power reset generating unit 30, an internal reset generating unit 40, a global reset generating unit 50, a reset delay unit 60, a reset counter unit 70, and a power controlling unit 80. According to at least one embodiment, the power reset generating unit 30, the internal reset generating unit 40, the global reset generating unit 50, and the reset delay unit 60 configure a low voltage detecting device.

According to at least one embodiment, the power supplying unit 20 serves to rectify a power applied from an external battery 10 to a predetermined voltage level appropriate for a chip. Thus, the power supplying unit provides a power rectified from a power of 12V applied from the battery 10 to a voltage level required for the chip to the chip.

According to at least one embodiment, the power reset generating unit 30 generates and outputs a power reset signal when the power supplying unit 20 is turned on to supply the power.

According to at least one embodiment, the power reset signal generated by the power reset generating unit 30 is an active high reset signal of which a reset condition is a high level state or an active low reset signal of which a reset condition is a low level state.

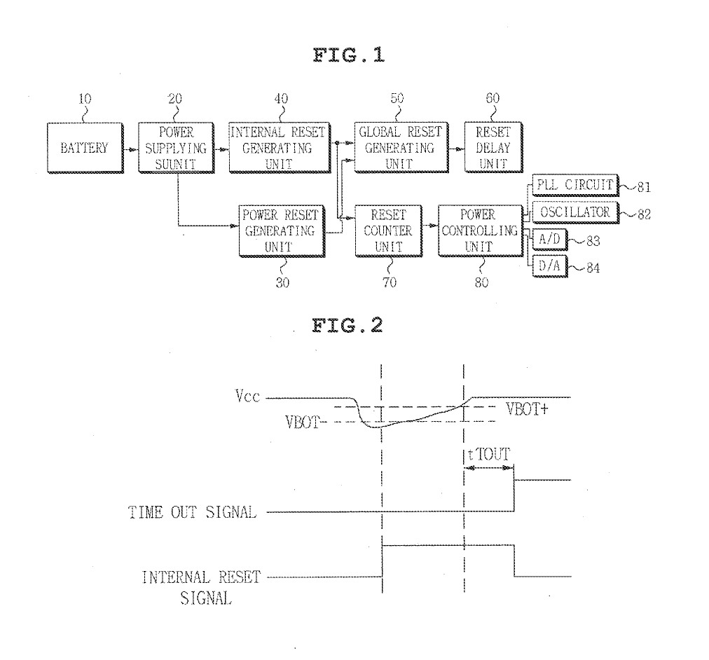

According to at least one embodiment, the internal reset generating unit 40 generates and outputs an internal reset signal when a power supplying voltage Vcc provided from the power supplying unit 20 is lowered from a voltage in a normal state to a voltage lower than a lower threshold voltage VBOT− as shown in FIG. 2. Then, the internal reset generating unit 40 releases a reset state of the internal reset signal when the power supplying voltage is raised to a voltage higher than an upper threshold voltage VBOT+ and a stabilized state is then maintained for a predetermined time tTOUT.

For reference, the voltage in the normal state means a voltage within a predetermined range from a voltage in a state in which the chip is the smoothest driven. For example, when it is assumed that a voltage of 5V is a voltage in a state in which the chip is the smoothest driven, the voltage in the normal state means a voltage within a range of ±5% from 5V.

According to at least one embodiment, the internal reset signal generated by the internal reset generating unit 40 is an active high reset signal of which a reset condition is a high level state (a signal shown in FIG. 2 corresponds to this case) or an active low reset signal of which a reset condition is a low level state.

According to at least one embodiment, the meaning that the internal reset generating unit 40 releases the internal reset signal is that the internal reset generating unit 40 adjusts a signal level to a low level state (see the internal reset signal shown in FIG. 2) when the internal reset signal was in a high level state in the case in which the reset condition of the internal reset signal is the high level state.

According to at least one embodiment, the meaning that the internal reset generating unit 40 releases the internal reset signal is that the internal reset generating unit 40 adjusts a signal level to a high level state when the internal reset signal was in a low level state in the case in which the reset condition of the internal reset signal output from the internal reset generating unit 40 is the low level state, unlike this.

Next, the global reset generating unit 50 receives the power reset signal output from the power reset generating unit 30 and the internal reset signal output from the internal reset generating unit 40 and generates and outputs a global reset signal.

According to at least one embodiment, the global reset generating unit 50 outputs the global reset signal in the case in which the power reset signal and the internal reset signal are in the same reset state.

Thus, the global reset generating unit 50 outputs the global reset signal in a high level state in the case in which the power reset signal is in the high level state in a state in which the reset condition is the high level and the internal reset signal is also in the high level state in a state in which the reset condition is the high level.

Unlike this, the global reset generating unit 50 outputs the global reset signal in a low level state in the case in which the power reset signal is in the low level state in a state in which the reset condition is the low level and the internal reset signal is also in the low level state in a state in which the reset condition is the low level.

According to at least one embodiment, the global reset generating unit 50 is operated in the case in which the power reset signal is in a reset state. Therefore, the global reset signal follows the internal reset signal.

Meanwhile, the reset delay unit 60 outputs the global reset signal of which a reset state is released after a predetermined time then elapses when the reset signal of the global reset signal output from the global reset generating unit 50 is released.

According to at least one embodiment, the reset delay unit 60 as described above is implemented by, for example, a plurality of inverters connected in series with each other, and delays the global reset signal output from the global reset generating unit 50 and outputs the delayed global reset signal to a microprocessor 61 of the chip.

Next, the reset counter unit 70 counts input clock signals and outputs the counted number of clocks, in the case in which the internal reset signal output from the internal reset generating unit 40 is in the reset state.

In this case, the power controlling unit 80 outputs a power down signal to a phase locked loop (PLL) circuit 81, an oscillator 82, an analog to digital converter 83, a digital to analog converter 84, as non-limiting examples, to allow a corresponding apparatus to enter a speed mode or stop an operation of the corresponding apparatus, in the case in which the number of clocks counted by the reset counter unit 70 is a predetermined number or more (for example, in the case in which a value obtained by converting the number of clocks into a time is 5 sec or more).

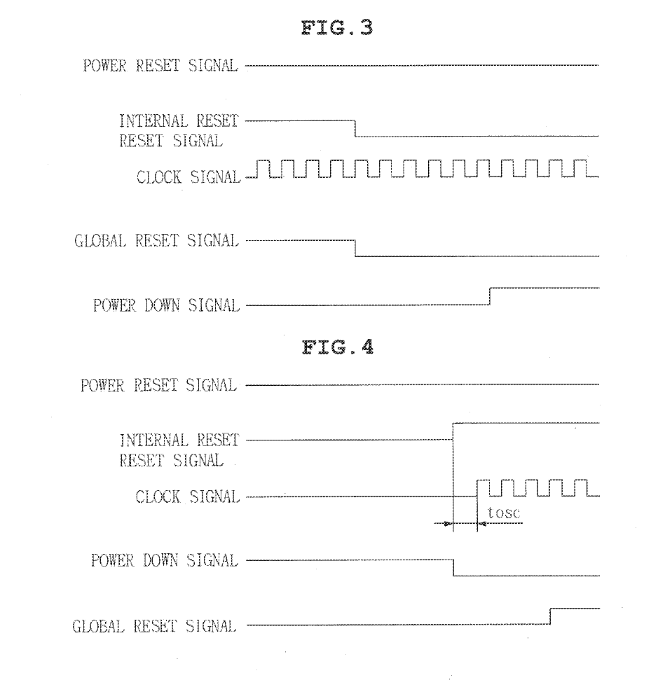

In connection with this, FIG. 3 shows a power down signal output from the power controlling unit 80. In detail, FIG. 3 shows that the power reset signal is in the reset signal, and the internal reset signal enters the reset state, such that the power down signal is changed into a turn-on state after a predetermined time elapses.

According to at least one embodiment, when the power down signal is changed into the turn-on state as described above, the PLL circuit 81, the oscillator 82, the analog to digital converter 83, the digital to analog converter 84, as non-limiting examples, receiving this signal enters the sleep mode or the operation thereof stops.

Meanwhile, when the reset state of the internal reset signal is released, the power controlling unit 80 releases a power down state of the power down signal.

Thus, as shown in FIG. 4, when the reset state of the internal reset signal is released, the power controlling unit 80 changes and outputs the power down signal from a high state to a low state.

According to at least one embodiment, when the power down state of the power down signal is released as described above, the PLL circuit 81, the oscillator 82, the analog to digital converter 83, the digital to analog converter 84, as non-limiting examples, receiving this signal departs from the sleep mode or the operation stop state to start a normal operation.

According to at least one embodiment, FIG. 4 shows an example of a clock signal output from the oscillator 82. It may be appreciated from FIG. 4 that a stabilized clock signal is output after a predetermined time elapses.

An operation of the power reduction device according to at least one embodiment of the invention configured as described above will be described.

According to at least one embodiment, when the power supplying unit 20 rectifies the power output from the battery 10 and supplies the power supplying voltage to the chip, the power reset generating unit 30 generates and outputs the power reset signal.

According to at least one embodiment, the internal reset generating unit 40 generates and outputs the internal reset signal when the power supplying voltage Vcc provided from the power supplying unit 20 is lowered to the voltage lower than the lower threshold voltage VBOT−. Then, the internal reset generating unit 40 releases the reset state of the internal reset signal when the power supplying voltage is raised to the voltage higher than the upper threshold voltage VBOT+ and the stabilized state is then maintained for the predetermined time tTOUT.

Therefore, the global reset generating unit 50 receives the power reset signal output from the power reset generating unit 30 and the internal reset signal output from the internal reset generating unit 40 and generates and outputs the global reset signal.

According to at least one embodiment, the global reset generating unit 50 outputs the global reset signal in the case in which the power reset signal and the internal reset signal are in the same reset state and is operated in the case in which the power reset signal is in the reset state. Therefore, the global reset signal follows the internal reset signal.

According to at least one embodiment, the reset delay unit 60 outputs the global reset signal of which the reset state is released after the predetermined time then elapses when the reset signal of the global reset signal output from the global reset generating unit 50 is released.

Meanwhile, the reset counter unit 70 counts the input clock signals and outputs the counted number of clocks, in the case in which the internal reset signal output from the internal reset generating unit 40 is in the reset state.

According to at least one embodiment, the power controlling unit 80 outputs the power down signal to the PLL circuit 81, the oscillator 82, the analog to digital converter 83, the digital to analog converter 84, as non-limiting examples, to allow the corresponding apparatus to enter the speed mode or stop the operation of the corresponding apparatus, in the case in which the number of clocks counted by the reset counter unit 70 is the predetermined number or more.

Meanwhile, when the reset state of the internal reset signal is released, the power controlling unit 80 releases the power down state of the power down signal.

According to at least one embodiment, when the power down signal is changed into a turn-off state as described above, the PLL circuit 81, the oscillator 82, the analog to digital converter 83, the digital to analog converter 84, as non-limiting examples, receiving this signal departs from the sleep mode or the operation stop state to start the normal operation.

According to at least one embodiment, the power down mode in the chip is operated when a power lower than a reference is provided for a long time, thereby making it possible to reduce a current consumed in the chip.

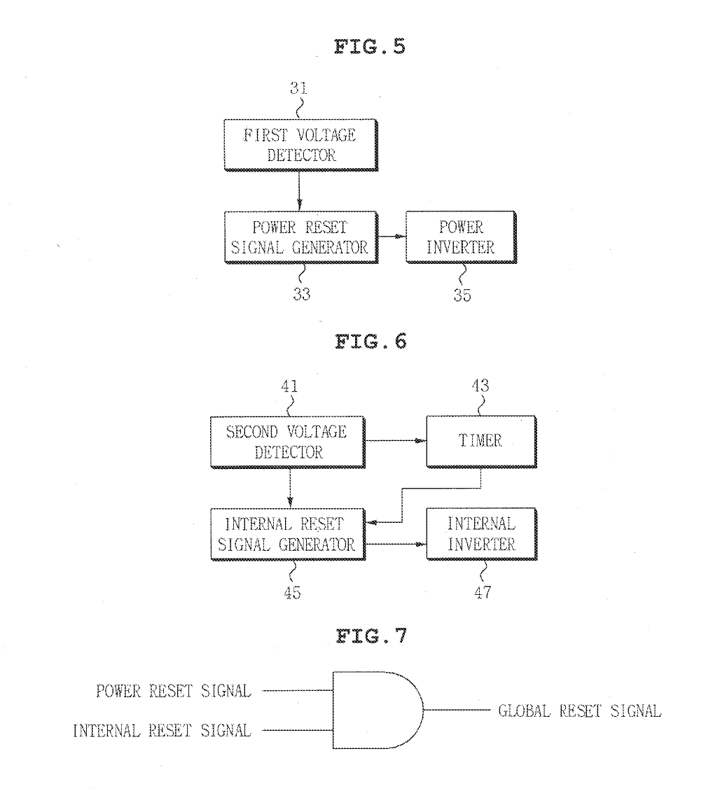

FIG. 5 is a detailed configuration diagram of a power reset generating unit of FIG. 1.

Referring to FIG. 5, the power reset generating unit of FIG. 1 is configured to include a first voltage detector 31, a power reset signal generator 33, and a power inverter 35.

According to at least one embodiment, the first voltage detector 31 detects a variation in the power supplying voltage supplied from the power supplying unit 20.

According to at least one embodiment, the first voltage detector 31 as described above is configured of a P channel metal oxide semiconductor (PMOS) transistor gate-driven by a ground voltage and having the power supplying voltage input thereto, an N-channel MOS (NMOS) transistor gate-driven by the power supplying voltage, and a plurality of resistor elements connected in series with each other between the PMOS transistor and the NMOS transistor and detects the variation in the power supplying voltage.

According to at least one embodiment, the power reset signal generator 33 generates and outputs the power reset signal in the case in which the power supplying voltage detected by the first voltage detector 31 is a first reference value or more. According to at least one embodiment, the first reference value is a voltage corresponding to 50% of the power supplying voltage when it is assumed that the power supplying voltage output from the power supplying unit 20 in a normal state is 100%, and a voltage condition is arbitrarily changed depending on a use environment.

According to at least one embodiment, the power reset signal generator 33 is configured of a PMOS series, which is a plurality of PMOS transistors connected in series with each other, gate-driven by the ground voltage, and having a power supply voltage input thereto, and an NMOS series, which is a plurality of NMOS transistors connected in series with each other, gate-driven by the output signal of the first voltage detector 31, and connected to a ground, and generates the reset signal depending on a change in an external voltage from a node between the PMOS series and the NMOS series.

Meanwhile, the power inverter 35 inverts and outputs the power reset signal output from the power reset signal generator 33.

According to at least one embodiment, the power reset signal generator 33 outputs an active high reset signal of which a reset condition is a high level state, and the power inverter 35 inverts the active high reset signal to output an active low reset signal of which a reset condition is a low level state.

In the power reduction device, in the case in which reset conditions of components after the power reset generating unit 30 are a high level state, the power inverter 35 is omitted.

An operation of the power reset generating unit 30 having the configuration as described above will be described below.

According to at least one embodiment, the first voltage detector 31 detects and outputs the power supplying voltage output from the power supplying unit 20.

Then, the power reset signal generator 33 generates and outputs the power reset signal in the case in which the power supplying voltage detected by the first voltage detector 31 is the first reference value or more.

According to at least one embodiment, the power inverter 35 inverts and outputs the power reset signal output from the power reset signal generator 33.

According to at least one embodiment, the power reset generating unit 30 generates and outputs a power reset signal by the above-mentioned operation when the power supplying unit 20 is turned on to supply the power.

FIG. 6 is a detailed configuration diagram of an internal reset generating unit of FIG. 1.

Referring to FIG. 6, the internal reset generating unit of FIG. 1 includes a second voltage detector 41, a timer 43, an internal reset signal generator 45, and an internal inverter 47.

According to at least one embodiment, the second voltage detector 41 detects the power supplying voltage supplied from the power supplying unit 20.

According to at least one embodiment, the second voltage detector 41 outputs a lower level detection signal when the power supplying voltage is maintained in a normal level state and is then lowered to a voltage lower than a lower threshold voltage.

According to at least one embodiment, the second voltage detector 41 detects the power supplying voltage provided from the power supplying unit 20 and outputs an upper level detection signal when the power supplying voltage is raised from a state in which it is lowered to the voltage lower than the lower threshold voltage to a voltage higher than an upper threshold voltage.

According to at least one embodiment, the second voltage detector 41 as described above decides that a state is a normal level state when the power supplying voltage is higher than the upper threshold voltage.

Next, the timer 43 outputs a time out signal after a predetermined time tTOUT elapses when the upper level detection signal is output from the second voltage detector.

Meanwhile, the internal reset signal generator 45 generates and outputs the internal reset signal when the lower level detection signal is output from the second voltage detector 41.

According to at least one embodiment, the internal reset signal generator 45 releases a reset state of the internal reset signal when the upper level detection signal is input from the second voltage detector 41 in a process of generating and outputting the internal reset signal and the time out signal is input from the timer 43 after a predetermined time elapses.

According to at least one embodiment, the meaning that the internal reset signal generator 45 releases the internal reset signal is that the internal reset signal generator 45 adjusts a signal level to a low level state when the internal reset signal was in a high level state in the case in which the reset condition of the internal reset signal is the high level state.

Further, the meaning that the internal reset signal generator 45 releases the internal reset signal is that the internal reset signal generator adjusts a signal level to a high level state when the internal reset signal was in a low level state in the case in which the reset condition of the internal reset signal output from the internal reset signal generator 45 is the low level state, unlike this.

An operation of the internal reset generating unit having the above-mentioned configuration will be described below.

According to at least one embodiment, the second voltage detector 41 generates and outputs the lower level detection signal when the power supplying voltage Vcc provided from the power supplying unit 20 is maintained in the normal level state and is then lowered to the voltage lower than the lower threshold voltage VBOT−.

According to at least one embodiment, the internal reset signal generator 45 generates and outputs the internal reset signal when the lower level detection signal is output from the second voltage detector 41.

According to at least one embodiment, the internal inverter 47 inverts and outputs the internal reset signal output from the internal reset signal generator 45.

Then, the second voltage detector 41 generates and outputs the upper level detection signal when the power supplying voltage Vcc provided from the power supplying unit 20 returns from a state in which it is lower than the lower threshold voltage to the normal level state and is then raised to the voltage higher than the upper threshold voltage.

According to at least one embodiment, when the upper level detection signal is generated by the second voltage detector 41 as described above, the timer 43 generates and outputs the time out signal when a predetermined time elapses.

According to at least one embodiment, when the time out signal is output from the timer 43 as described above, the internal reset signal generator 45 releases the reset state of the internal reset signal.

Through the above-mentioned operation, the internal reset generating unit 40 generates and outputs the internal reset signal when the power supplying voltage Vcc provided from the power supplying unit 20 is lowered to the voltage lower than the lower threshold voltage VBOT−. According to at least one embodiment, the internal reset generating unit 40 releases the reset state of the internal reset signal when the power supplying voltage is raised to the voltage higher than the upper threshold voltage VBOT+ and the stabilized state is then maintained for the predetermined time tTOUT.

Meanwhile, the internal reset signal generator 45 described above is implemented so as to release the reset state of the internal reset signal using the time out signal input from the timer 43.

However, embodiment of the invention are not limited thereto. That is, the internal reset signal generator 45 is also implemented to have timer function to decide whether a predetermined time has elapsed when the upper level detection signal is input from the second voltage detector 41 and release the reset state of the internal reset signal when it is decided that the predetermined time has elapsed.

FIG. 7 is a configuration diagram showing the case in which the global reset generating unit is configured of a logical product circuit 51 of FIG. 1.

Referring to FIG. 7, the global reset generating unit of FIG. 1 is configured of the logical product circuit 51 receiving the power reset signal and the internal reset signal and generating the global reset signal.

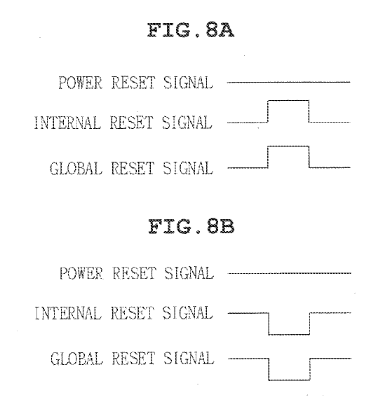

Here, FIG. 8A shows a signal waveform in the case in which the power reset signal output from the power reset generating unit 30 is input without passing through a power inverter and shows a signal waveform in the case in which the internal reset signal output from the internal reset generating unit 40 is input without passing through an internal inverter.

According to at least one embodiment, FIG. 8A shows a global reset signal output in the case in which the power reset signal and the internal reset signal as described above are input to the logical product circuit 51.

According to at least one embodiment, the global reset signal output from the logical product circuit 51 is changed from a low state to a high state when the internal reset signal is changed to a high state in a state in which the power reset signal is maintained in a high state, as shown in FIG. 8A.

According to at least one embodiment, the global reset signal output from the logical product circuit 51 is changed from the high state to the low state when the internal reset signal is changed to the low state in the state in which the power reset signal is maintained in the high state, as shown in FIG. 8A.

Meanwhile, FIG. 8B shows a signal waveform in the case in which the power reset signal output from the power reset generating unit 30 is input with passing through a power inverter and shows a signal waveform in the case in which the internal reset signal output from the internal reset generating unit 40 is input with passing through an internal inverter.

According to at least one embodiment, FIG. 8B shows a global reset signal output in the case in which the power reset signal and the internal reset signal as described above are input to the logical product circuit 51.

According to at least one embodiment, the global reset signal output from the logical product circuit 51 is changed from the high state to the low state when the internal reset signal is changed to the low state in the state in which the power reset signal is maintained in the low state, as shown in FIG. 8B.

According to at least one embodiment, the global reset signal output from the logical product circuit 51 is changed from the low state to the high state when the internal reset signal is changed to the high state in the state in which the power reset signal is maintained in the low state, as shown in FIG. 8B.

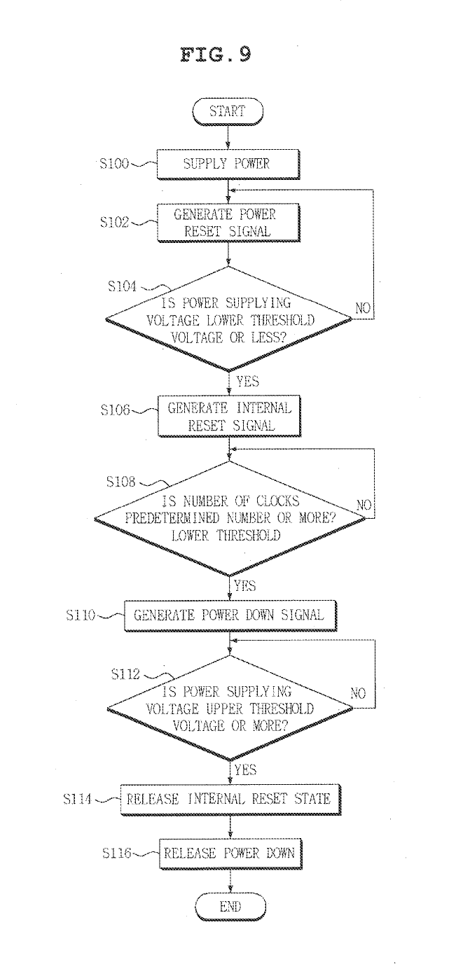

FIG. 9 is a flow chart of a power reduction method according to a preferred embodiment of the present invention.

Referring to FIG. 9, the power supplying unit rectifies the power applied from the external battery to the predetermined voltage level appropriate for the chip and provides the rectified power to the chip (S100).

Then, the power reset generating unit generates and outputs the power reset signal (S102) when the power supplying unit is turned on to supply the power.

In more detail, step S102 includes a step of detecting, by the power reset generating unit, a variation of the power supplying voltage, a step of generating, by the power reset generating unit, the power reset signal when the detected power supplying voltage is equal to or larger than a predetermined ratio of a normal state, and inverting and outputting, by the power reset generating unit, the power reset signal.

According to at least one embodiment, the power reset signal generated by the power reset generating unit is the active high reset signal of which the reset condition is the high level state or the active low reset signal of which the reset condition is the low level state.

Meanwhile, the internal reset generating unit decides whether or not the power supplying voltage Vcc provided from the power supplying unit is within a range of the normal state and is then lowered to the voltage lower than the lower threshold voltage VBOT− (S104).

It is decided that the power supplying voltage Vcc provided from the power supplying unit is within the range of the normal state and is then lowered to the voltage lower than the lower threshold voltage VBOT−, the internal reset generating unit generates and outputs the internal reset signal (S106).

According to at least one embodiment, the internal reset signal generated by the internal reset generating unit is the active high reset signal of which the reset condition is the high level state (the signal shown in FIG. 2 corresponds to this case) or the active low reset signal of which the reset condition is the low level state.

In more detail, step S106 includes a step of detecting, by the internal reset generating unit, a variation of the power supplying voltage, a step of generating, by the internal reset generating unit, the internal reset signal when the detected power supplying voltage is lowered from the normal state to the lower threshold voltage or less, and inverting and outputting, by the internal reset generating unit, the internal reset signal.

Meanwhile, in this case, the global reset generating unit receives the power reset signal output from the power reset generating unit and the internal reset signal output from the internal reset generating unit and generates and outputs the global reset signal.

According to at least one embodiment, the global reset generating unit outputs the global reset signal in the case in which the power reset signal and the internal reset signal are in the same reset state.

According to at least one embodiment, the reset delay unit outputs the global reset signal of which the reset state is released after the predetermined time then elapses when the reset signal of the global reset signal output from the global reset generating unit is released.

Meanwhile, the reset counter unit counts the input clock signals and outputs the counted number of clocks (S108) in the case in which the internal reset signal output from the internal reset generating unit is in the reset state.

Then, the power controlling unit outputs the power down signal to the PLL circuit, the oscillator, the analog to digital converter, the digital to analog converter, as non-limiting examples, to allow a corresponding apparatus to enter the speed mode or stop the operation of the corresponding apparatus (S110), in the case in which the number of clocks counted by the reset counter unit is a predetermined number or more.

According to at least one embodiment, when the power down signal is changed into the turn-on state as described above, the PLL circuit, the oscillator, the analog to digital converter, the digital to analog converter, as non-limiting examples, receiving this signal enters the sleep mode or the operation thereof stops.

In this state, the internal reset generating unit decides whether or not the power supplying voltage is raised to the voltage higher than the upper threshold voltage VBOT+ (S112).

According to at least one embodiment, when it is decided that the power supplying voltage is raised to the voltage higher than the upper threshold voltage and the stabilized state is then maintained for a predetermined time tTOUT, the internal reset generating unit releases the reset state of the internal reset signal (S114).

Meanwhile, when the reset state of the internal reset signal is released, the power controlling unit releases the power down state of the power down signal (S116).

According to at least one embodiment, when the power down signal is changed into the turn-off state as described above, the PLL circuit, the oscillator, the analog to digital converter, the digital to analog converter, as non-limiting examples, receiving this signal departs from the sleep mode or the operation stop state to start the normal operation.

According to at least one embodiment of the invention as described above, the power down mode in the chip is operated when a power lower than a reference is provided for a long time, thereby making it possible to reduce a current consumed in the chip.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A power reduction device, comprising:
an internal reset generating unit configured to output an internal reset signal when a power supplying voltage is lowered from a normal state to a lower threshold voltage or less; and
a power controlling unit configured to output a power down signal after a predetermined time elapses when the internal reset signal is output from the internal reset generating unit.

2. The power reduction device as set forth in claim 1, further comprising:
a power reset generating unit configured to generate and output a power reset signal when the power supplying voltage is equal to or larger than a predetermined ratio of the normal state;
a global reset generating unit configured to output a global reset signal when the power reset signal output from the power reset generating unit and the internal reset signal output from the internal reset generating unit are in the same reset state; and
a reset delay unit configured to delay and output the global reset signal output from the global reset generating unit.

3. The power reduction device as set forth in claim 2, wherein the power reset generating unit comprises:
a first voltage detector configured to detect a variation in the power supplying voltage;
a power reset signal generator configured to generate and output the power reset signal when the power supplying voltage detected by the first voltage detector is equal to or larger than the predetermined ratio of the normal state; and
a power inverter configured to invert and output the power reset signal.

4. The power reduction device as set forth in claim 2, wherein the global reset generating unit is a logical product circuit configured to output the global reset signal when the power reset signal output from the power reset generating unit and the internal reset signal output from the internal reset generating unit are in the same reset state.

5. The power reduction device as set forth in claim 1, further comprising:
a reset counter unit configured to count the number of clocks of a clock signal and to output the counted number of clocks when the internal reset signal is output from the internal reset generating unit,
wherein the power controlling unit is configured to decide that the predetermined time has elapsed to output the power down signal, when the number of clocks input from the reset counter unit is a predetermined number or more.

6. The power reduction device as set forth in claim 1, wherein the internal reset generating unit comprises:
a second voltage detector configured to detect a variation in the power supplying voltage;
an internal reset signal generator configured to generate and output the internal reset signal when the power supplying voltage detected by the second voltage detector is lowered from the normal state to the lower threshold voltage or less; and
an internal inverter configured to invert and output the internal reset signal.

7. The power reduction device as set forth in claim 1, wherein the internal reset generating unit is configured to release a reset state of the internal reset signal after a predetermined time elapses when the power supplying voltage is raised from the lower threshold voltage or less to an upper threshold voltage or more, and
the power controlling unit is configured to release a power down state of the power down signal when the reset state of the internal reset signal is released by the internal reset generating unit.

8. The power reduction device as set forth in claim 1, wherein the power controlling unit is configured to output the power down signal to at least one of a phase locked loop (PLL) circuit, an oscillator, an analog to digital converter, and a digital to analog converter.

9. A power reduction method, comprising:
(A) outputting, by an internal reset generating unit, an internal reset signal when a power supplying voltage is lowered from a normal state to a lower threshold voltage or less; and
(B) outputting, by a power controlling unit, a power down signal after a predetermined time elapses when the internal reset signal is output from the internal reset generating unit.

10. The power reduction method as set forth in claim 9, further comprising:
before the step (A), (C) generating and outputting, by a power reset generating unit, a power reset signal when the power supplying voltage is equal to or larger than a predetermined ratio of the normal state; and after the step (A), (D) outputting, by a global reset generating unit, a global reset signal when the power reset signal output from the power reset generating unit and the internal reset signal output from the internal reset generating unit are in the same reset state; and (E) delaying and outputting, by a reset delay unit, the global reset signal output from the global reset generating unit.

11. The power reduction method as set forth in claim 10, wherein the step (C) comprises:
(C-1) detecting, by the power reset generating unit, a variation in the power supplying voltage;
(C-2) generating, by the power reset generating unit, the power reset signal when the detected power supplying voltage is equal to or larger than the predetermined ratio of the normal state; and
(C-3) inverting and outputting, by the power reset generating unit, the power reset signal.

12. The power reduction method as set forth in claim 9, further comprising:
before the step (B), (F) counting the number of clocks of a clock signal and outputting the counted number of clocks, by a reset counter unit, when the internal reset signal is output from the internal reset generating unit,
wherein the power controlling unit decides that the predetermined time has elapsed to output the power down signal, when the number of clocks input from the reset counter unit is a predetermined number or more.

13. The power reduction method as set forth in claim 9, wherein the step (A) comprises:
(A-1) detecting, by the internal reset generating unit, a variation in the power supplying voltage;
(A-2) generating, by the internal reset generating unit, the internal reset signal when the detected power supplying voltage is lowered from the normal state to the lower threshold voltage or less; and
(A-3) inverting and outputting, by the internal reset generating unit, the internal reset signal.

14. The power reduction method as set forth in claim 9, further comprising:
(G) releasing, by the internal reset generating unit, a reset state of the internal reset signal after a predetermined time elapses when the power supplying voltage is raised from the lower threshold voltage or less to an upper threshold voltage or more; and
(H) releasing, by the power controlling unit, a power down state of the power down signal when the reset state of the internal reset signal is released by the internal reset generating unit.

15. The power reduction method as set forth in claim 9, wherein in the step (B), the power controlling unit outputs the power down signal to at least one of a PLL circuit, an oscillator, an analog to digital converter, and a digital to analog converter.
